(19) United States
(12) Patent Application Publication
(10) Pub. No.: US 2025/0389701 A1
(43) Pub. Date: Dec. 25, 2025

(54) NON-TRANSITORY COMPUTER-READABLE RECORDING MEDIUM, CALCULATION METHOD AND INFORMATION PROCESSING DEVICE

(71) Applicant: Fujitsu Limited, Kawasaki-shi (JP)

(72) Inventor: Yuji KATAOKA, Yokohama (JP)

(73) Assignee: Fujitsu Limited, Kawasaki-shi (JP)

(21) Appl. No.: 19/311,143

(22) Filed: Aug. 27, 2025

Related U.S. Application Data
(63) Continuation of application No. PCT/JP2023/046545, filed on Dec. 26, 2023.

(30) Foreign Application Priority Data
Feb. 28, 2023 (JP) 2023-029748

(51) Int. Cl. G01N 30/86; G06F 17/17

(52) U.S. Cl. CPC G01N 30/8641; G01N 30/8631; G01N 30/8658; G06F 17/17

(57) ABSTRACT

A calculation program causes a computer to execute a process including an acquisition process of changing a parameter for identifying a baseline to multiple values to obtain multiple estimated baselines estimated for each of the multiple values, an identification process of identifying peaks in multiple graphs that represent differences between a base data of spectral data and each of the multiple estimated baselines, and a selection process of selecting a first graph from the multiple graphs according to a number of peaks and a peak area of each of the multiple graphs, when identifying the baseline using a nonlinear least squares method for the base data.

### CROSS-REFERENCE TO RELATED APPLICATIONS

This application is a continuation application of PCT/JP2023/046545, filed on Dec. 26, 2023, which is based upon and claims the benefit of priority of the prior Japanese Patent Application No. 2023-029748, filed on Feb. 28, 2023, the entire contents of each are incorporated herein by reference.

### FIELD

A certain aspect of embodiments described herein relates to a non-transitory computer-readable recording medium, a calculation method and an information processing device.

### BACKGROUND ART

Spectral data may contain a baseline. To remove the baseline from the spectral data, a method using the nonlinear least squares method has been proposed (see, for example, P. H. C. Eilers, Anal. Chem., 75, 3631-3636 (2003), and Z.-M. Zhang, S. Chen, and Y.-Z. Liang, Baseline correction using adaptive iteratively reweighted penalized least squares, and Sung-June Baek, Aaron Park, Young-Jin Ahn and Jaebum Choo, Baseline correction using asymmetrically reweighted penalized least squares smoothing, Analyst, 140, 250-257 (2015).

### SUMMARY

In one aspect, there is provided a non-transitory computer-readable recording medium that stores a program causing a computer to execute a process, the process including: an acquisition process of changing a parameter for identifying a baseline to multiple values to obtain multiple estimated baselines estimated for each of the multiple values, an identification process of identifying peaks in multiple graphs that represent differences between a base data of spectral data and each of the multiple estimated baselines, and a selection process of selecting a first graph from the multiple graphs according to a number of peaks and a peak area of each of the multiple graphs, when identifying the baseline using a nonlinear least squares method for the base data.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF THE DRAWINGS

FIG. 1 is a flowchart of a baseline estimation method using a nonlinear least squares method.

FIG. 2A is a block diagram illustrating an example of an overall configuration of an information processing device, and FIG. 2B is a block diagram illustrating an example of a hardware configuration of an information processing device.

FIG. 3 is a flowchart of an example of an operation of an information processing device.

FIG. 4 is a flowchart of an example of an operation of an information processing device.

FIG. 5 is a measured spectrum obtained by X-ray absorption spectroscopy.

FIG. 6 illustrates results obtained by estimating a baseline using nonlinear least squares method for a measured spectrum in FIG. 5.

FIG. 7 is only a corrected spectrum extracted from FIG. 6.

FIG. 8A to FIG. 8D illustrate results when values of a parameter λ and a parameter ratio are changed.

FIG. 9 is a diagram illustrating a base data, a corrected baseline, a corrected spectrum, and a baseline.

### DESCRIPTION OF EMBODIMENTS

It is difficult to estimate the baseline appropriately.

Physical and chemical analyses such as nuclear magnetic resonance, Raman spectroscopy, infrared absorption spectroscopy, X-ray photoelectron spectroscopy, or X-ray absorption spectroscopy are performed to obtain physical and chemical information of the analytical sample. The signals (spectral data) obtained by these analyses contain a baseline and noise. The baseline and the noise prevent the acquisition of desired information. In particular, the baseline may obscure part of the desired information or bury the desired information entirely. Therefore, baseline correction is required to remove the baseline appropriately.

Conventionally, methods using differentiation and methods using polynomial fitting have been used for this baseline correction. The differentiation method is a method in which the spectrum is differentiated to highlight the peaks. The polynomial fitting method is a method in which a function that is likely to be able to express the shape of the background is used for fitting using the least squares method or the like. However, even with these methods, baseline correction can be difficult in some cases.

In recent years, a method using a nonlinear least squares method incorporating a penalty term has been proposed and its effectiveness has been recognized. In the method using the nonlinear least squares method, assuming that there is a measured value y (vertical axis of the spectrum) for x (horizontal axis of the spectrum), the evaluation function Q is expressed using the degree of fit F of the estimated value with w as a weight and the degree of smoothness R of the estimated value, and the baseline estimate z is obtained. λ is a parameter used for adjustment, and is a so-called hyperparameter.

$$x = ( {x}_{0} , {x}_{1} , … , {x}_{i} ) , y = ( {y}_{0} , {y}_{1} , … , {y}_{i} ) , z = ( {z}_{0} , {z}_{1} , … , {z}_{i} ) \qquad [ Equation 1 ]$$

$$w = ( {w}_{0} , {w}_{1} , … , {w}_{i} ) \qquad [ Equation 2 ]$$

$$F = {{\sum }^{m}}_{i = 1} {{w}_{i} ( {y}_{i} - {z}_{i} )}^{2} \qquad [ Equation 3 ]$$

$$R = {{\sum }^{m}}_{i = 2} {( {z}_{i} - {z}_{i - 1} )}^{2} = {{\sum }^{m - 1}}_{i = 1} ( Δ {z}_{i} ) \qquad [ Equation 4 ]$$

$$Q = F + λ R = W {‖ y - z ‖}^{2} + {λ 〚 Dz 〛}^{2} \qquad [ Equation 5 ]$$

$$D = [ \begin{matrix}1 & - 2 & 1 & 0 & … & 0 & 0 & 0 \\ 0 & 1 & - 2 & 1 & … & 0 & 0 & 0 \\ ⋮ & ⋮ & ⋮ & ⋮ & ⋱ & ⋮ & ⋮ & ⋮ \\ 0 & 0 & 0 & … & … & 1 & - 2 & 1\end{matrix} ] \qquad [ Equation 6 ]$$

$$Dz = Δ z \qquad [ Equation 7 ]$$

Finally, the baseline estimate Z can be expressed as the upper equation in the following equations. The weight W is a diagonal matrix, and can be expressed as the lower equation in the following equations with p as a parameter. Given the parameters λ and p, the weight W is iteratively determined based on the lower equation, and the upper equation is solved to update the baseline estimate Z. Then, when the weight W becomes constant or reaches a preset value, the iteration ends and the final baseline estimate Z is determined.

$$z = {( W + λ {D}^{T} D )}^{- 1} Wy \qquad [ Equation 8 ]$$

$${w}_{i} = \{ \begin{matrix}p , {y}_{i} > {z}_{i} \\ 1 - p , {y}_{i} \leq {z}_{i}\end{matrix} \qquad [ Equation 9 ]$$

In order to obtain the optimal baseline estimate Z, it is necessary to optimize the parameters λ and p, but in this case, the parameters λ and p are always constant. However, in order to estimate the baseline estimate Z with higher accuracy, it is necessary to set the weight wᵢ based on the difference between the original signal yᵢ and the zᵢ obtained in the previous iteration as expressed in the following equation.

$${F}^{′} = {\sum }_{i = 1}^{m} {{w}_{i}^{t} ( {y}_{i} - {z}_{i}^{t} )}^{2} \qquad [ Equation 10 ]$$

$${R}^{′} = {\sum }_{i = 2}^{m} {( {z}_{i}^{t} - {z}_{i - 1}^{t} )}^{2} \qquad [ Equation 11 ]$$

$${Q}^{′} = {F}^{′} + λ {R}^{′} \qquad [ Equation 12 ]$$

In this method, the weight vector W is obtained by the iteration step t as expressed in the following equations.

$${w}_{i}^{t} = \{ \begin{matrix}0 , {y}_{i} \geq {z}_{i}^{t - 1} \\ {e}^{\frac{t ( {y}_{i} - {z}_{i}^{t - 1} )}{\vert {d}^{t} \vert}} , {y}_{i} < {z}_{i}^{t - 1}\end{matrix} \qquad [ Equation 13 ]$$

$${d}^{t} = y - {z}^{t - 1} \qquad [ Equation 14 ]$$

In this case, the iteration ends when the specified number of iterations or the limit expressed in the following equation is reached.

$$\vert {d}^{t} \vert < 0.001 \times \vert x \vert \qquad [ Equation 15 ]$$

However, even with this method, problems can occur. When the original signal is higher than the fitted baseline, that is, when the following equation is satisfied, the weight is always zero, and when the original signal is lower than the fitted baseline, the weight becomes larger.

$${y}_{i} \geq {z}_{i}^{t - 1} \qquad [ Formula 16 ]$$

As a result, the baseline finally obtained is estimated low in areas without peaks, and the height of the peak after baseline correction may be higher than the actual height. Therefore, a method of setting the weight as expressed in the following equation has been proposed.

$${w}_{i}^{t} = \{ \begin{matrix}\begin{matrix}logistic ( {y}_{i} - {z}_{i}^{t - 1} , {m}_{{d}^{-}} , {σ}_{{d}^{-}} ) , & {y}_{i} < {z}_{i}^{t - 1}\end{matrix} \\ \begin{matrix}1 , & {y}_{i} \geq {z}_{i}^{t - 1}\end{matrix}\end{matrix} \qquad [ Formula 17 ]$$

$$logistic ( {d}^{t} , m , σ ) = \frac{1}{1 + {e}^{\frac{2 ( d - ( - m + 2 σ ) )}{σ}}} \qquad [ Formula 18 ]$$

$${d}^{t} = y - {z}^{t - 1} \qquad [ Formula 19 ]$$

$$\begin{matrix}{d}^{-} : d when {y}_{i} < {z}_{i}^{t - 1} , & {m}_{{d}^{-}} : average of {d}^{-} , & {σ}_{{d}^{-}} : standard deviation of {d}^{-}\end{matrix} \qquad [ Formula 20 ]$$

The iterations are repeated based on the preset parameter ratio until the relationship in the following equation is satisfied. The parameter ratio is a parameter related to the rate of change of the weight when performing iterative processing while varying the weight in the nonlinear least squares method.

$$\frac{\vert {w}^{t} - {w}^{t - 1} \vert}{\vert {w}^{t} \vert} < ratio \qquad [ Equation 21 ]$$

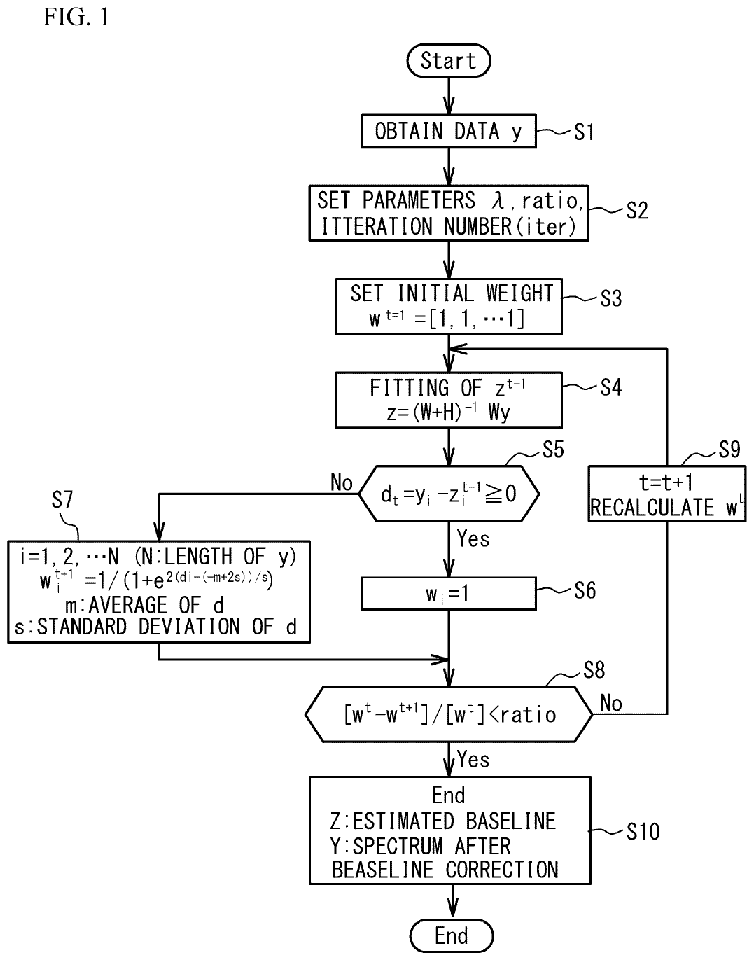

This method of setting weights as described above is considered to be the most accurate baseline estimation method among the methods using the nonlinear least squares method. FIG. 1 is a flowchart of the method.

As illustrated in FIG. 1, first, the base data y of the spectrum data is obtained (step S1). Next, the parameter 2, the parameter ratio, and the number of iterations iter are set (step S2). The number of iterations iter determines the upper limit of the iteration step t. Next, the initial weight w^{t=1}=[1, 1, . . . , 1] is set (step S3).

Next, fitting of z^{t-1} is performed (step S4). Specifically, z=(W+H)⁻¹Wy. Next, it is determined whether dₜ=yᵢ−z^{t-1} is equal to or greater than 0 (step S5). If the result of step S5 is “Yes”, the calculator 30 sets the weight wᵢ to 1 (step S6). If the result of step S5 is “No”, it sets i=1, 2, . . . , N (N: length of y) and wᵢ^{t+1}=1/{1+e^{2(di-(-m+2s))/s}} (step S7). Note that m is the average of d. s is the standard deviation of d.

After executing step S6 or step S7, it is determined whether [wt−w^{t+1}]/[w^{t}] is less than the parameter ratio (step S8).

If the result of step S8 is “No,” t=t+1 is used to recalculate w^{t} (step S9). Then, the process is repeated from step S4.

If the result of step S8 is “Yes,” Z is output as the estimated baseline, and Y is output as the spectrum after baseline correction (step S10).

Compared to the method using differentiation or the method using polynomial fitting, the method using the nonlinear least squares method is more versatile, and the estimation accuracy can be improved by devising the weighting on the degree of fit F. In particular, the method using the weighting as described above shows a significant improvement in the estimated value. However, in order to estimate an appropriate baseline, it is necessary to optimize the parameters for obtaining the baseline estimation value. The criteria for optimizing the parameters have not yet been clarified, and the current situation is that a baseline that is considered appropriate is estimated subjectively through repeated trial and error. Therefore, when comparing different spectra, it is difficult to quantitatively evaluate peak intensity and the like in the spectrum after baseline correction, or to find minute differences.

In the following embodiment, an example is described in which a baseline estimate can be obtained with high accuracy by optimizing parameters for obtaining a baseline estimate in the nonlinear least squares method.

### EMBODIMENT

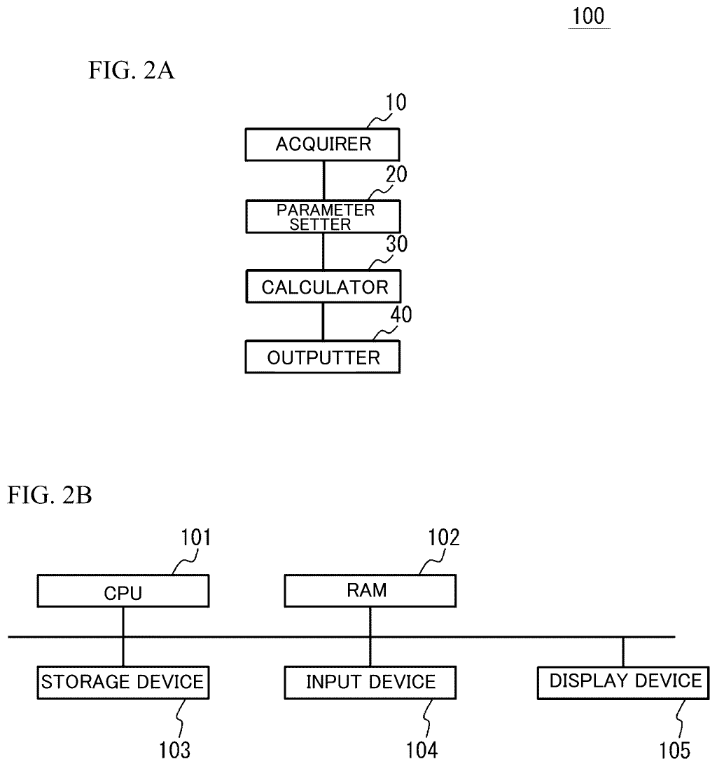

FIG. 2A is a block diagram illustrating an example of the overall configuration of an information processing device 100. As illustrated in FIG. 2A, the information processing device 100 includes an acquirer 10, a parameter setter 20, a calculator 30, and an outputter 40.

FIG. 2B is a block diagram illustrating an example of the hardware configuration of the information processing device 100. As illustrated in FIG. 2B, the information processing device 100 includes a CPU 101, a RAM 102, a storage device 103, an input device 104, a display device 105, and the like.

The CPU (Central Processing Unit) 101 is a central processing unit. The CPU 101 includes one or more cores. The RAM (Random Access Memory) 102 is a volatile memory that temporarily stores the program executed by the CPU 101, the data processed by the CPU 101, and the like. The storage device 103 is a non-volatile storage device. For example, a ROM (Read Only Memory), a solid state drive (SSD) such as a flash memory, or a hard disk driven by a hard disk drive can be used as the storage device 103. The storage device 103 stores a calculation program. The input device 104 is an input device such as a keyboard or a mouse. The display device 105 is a display device such as an LCD (Liquid Crystal Display). The CPU 101 executes the calculation program to realize the acquirer 10, the parameter setter 20, the calculator 30, the outputter 40, and the like. Note that hardware such as a dedicated circuit may be used as the acquirer 10, the parameter setter 20, the calculator 30, and the outputter 40, and the like.

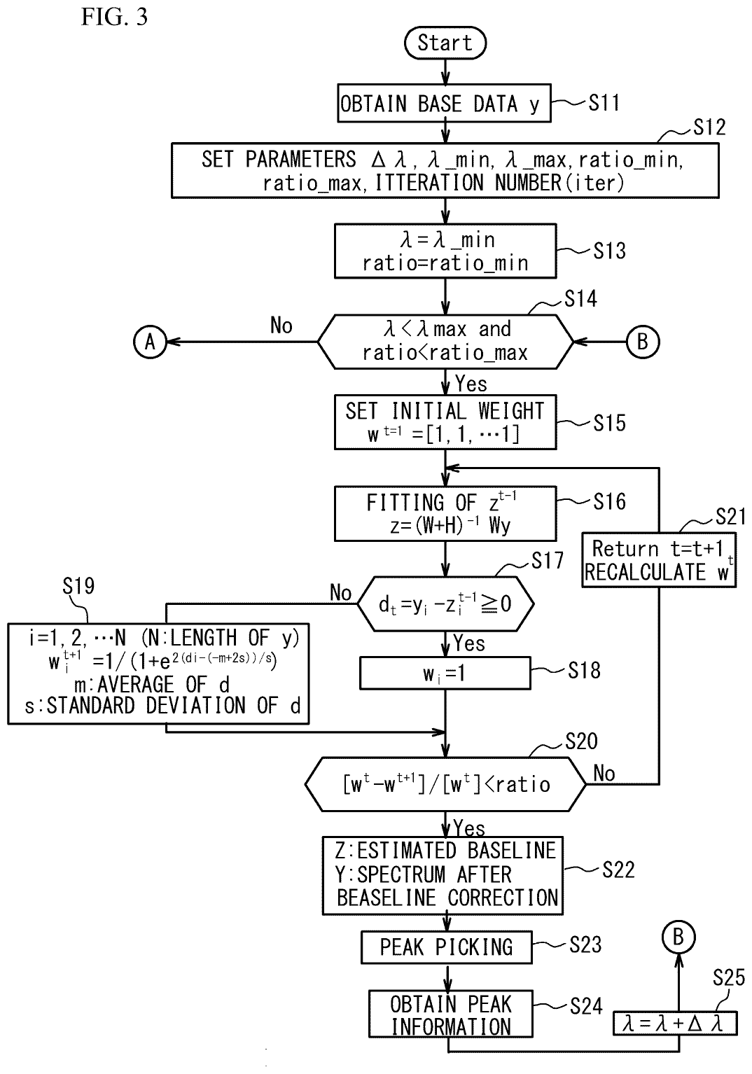

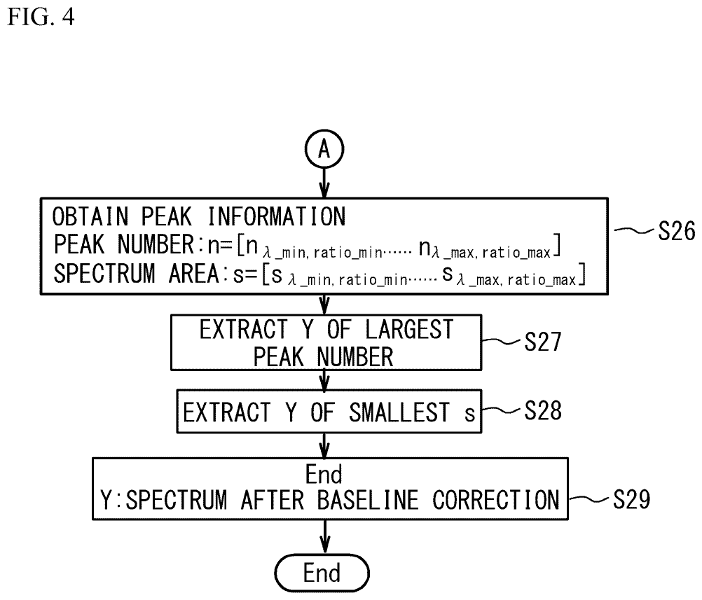

FIG. 3 and FIG. 4 are flowcharts of an example of the operation of the information processing device 100. As illustrated in FIG. 3 and FIG. 4, the acquirer unit 10 acquires base data y of the measured spectrum (step S11).

Next, the parameter setter 20 sets each parameter (step S12). Specifically, the parameter setter 20 sets Δλ, λ_min, λ_max, ratio_min, ratio_max, and the number of iterations (iter). λ_min is the minimum value of the parameter λ. λ_max is the maximum value of the parameter λ. ratio_min is the minimum value of the parameter ratio. ratio_max is the maximum value of the parameter ratio. Δλ is the range of change when λ is changed. The number of iterations iter determines the upper limit of the iteration step t.

The calculator 30 sets the parameter λ to λ_min and the parameter ratio to ratio_min (step S13). By executing step S13, the initial value of the parameter λ is set to λ_min, and the initial value of the parameter ratio is set to ratio_min.

The calculator 30 then determines whether the parameter λ is smaller than λ_max and the parameter ratio is smaller than ratio_max (step S14). By executing step S14, it is possible to confirm that the parameters λ and ratio have not reached their upper limits.

If the result of step S14 is “Yes,” the calculator 30 sets an initial weight (step S15). Specifically, the calculator 30 sets the initial weight w^{t}=1 to [1, 1, . . . , 1].

The calculator 30 then performs fitting of z^{t-1} (step S16). Specifically, the calculator 30 sets z=(W+H)⁻¹Wy.

Then, the calculator 30 judges whether dₜ=yᵢ−zᵢ^{t-1} is equal to or greater than 0 (step S17).

If the result of step S17 is “Yes”, the calculator 30 sets the weight wᵢ to 1 (step S18).

If the result of step S17 is “No”, the calculator 30 sets i=1, 2, . . . , N (N: length of y) and wᵢ^{t+1}=1/{1+e^{2(di-(-m+2s))/s}} (step S19). Note that m is the average of d. s is the standard deviation of d.

After executing step S18 or step S19, the calculator 30 judges whether [w^{t}−w^{t+1}]/[w^{t}] is less than the parameter ratio (step S20).

If the result of step S20 is “No,” the calculator 30 recalculates w^{t} by setting t=t+1 (step S21). Then, the process is executed again from step S16.

If the result in step S20 is “Yes,” the calculator 30 sets Z as the estimated baseline and Y as the baseline-corrected correction spectrum (step S22). The correction spectrum corresponds to a graph showing the difference between the base data and the estimated baseline.

The calculator 30 then detects peaks by picking peaks in the correction spectrum Y (step S23). Specifically, the calculator 30 detects peaks in the correction spectrum and valleys formed by the peaks.

The calculator 30 then acquires spectral information on the correction spectrum Y (step S24). Specifically, the calculator 30 acquires the number of peaks n and the peak area s of the correction spectrum Y. The calculator 30 then adds Δλ to λ (step S25). After that, the process is executed again from step S14.

If the result is “No” in step S14, the calculator 30 obtains the number of peaks n=[n_{λ_min, ratio_min}, . . . , n_{λ_max, ratio_max}] and the peak area s=[s_{λ_min, ratio_min}, . . . , s_{λ_max, ratio_max}] (step S26).

Next, the calculator 30 extracts the corrected spectrum Y with the largest number of peaks (step S27).

Next, the calculator 30 extracts the correction spectrum Y with the smallest peak area s from among the correction spectra Y extracted in step S27 (step S28). If only one correction spectrum Y is extracted in step S27, the one correction spectrum is extracted.

Next, the outputter 40 outputs the Y extracted in steps S27 and S28 as a baseline correction spectrum (step S29). The information output by the outputter 40 is displayed on the display device 105.

According to this embodiment, when the baseline is specified using the nonlinear least squares method for the base data, the parameters for specifying the baseline are changed to multiple values, and multiple estimated baselines are repeatedly obtained for each value. This allows the parameters to be changed widely. Furthermore, peak locations are specified in multiple graphs representing the differences between the base data and each of the multiple estimated baselines, and a predetermined graph is selected from the multiple graphs according to the number of peaks and the peak area of each graph. This allows the baseline to be estimated with high accuracy. The effect will be explained below for specific spectra.

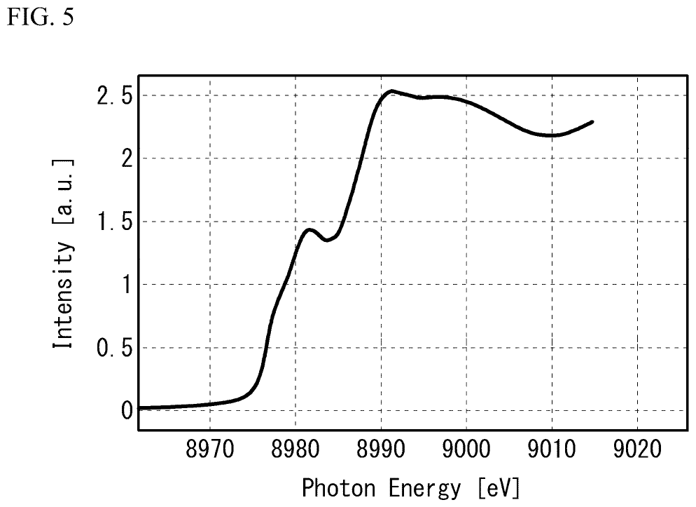

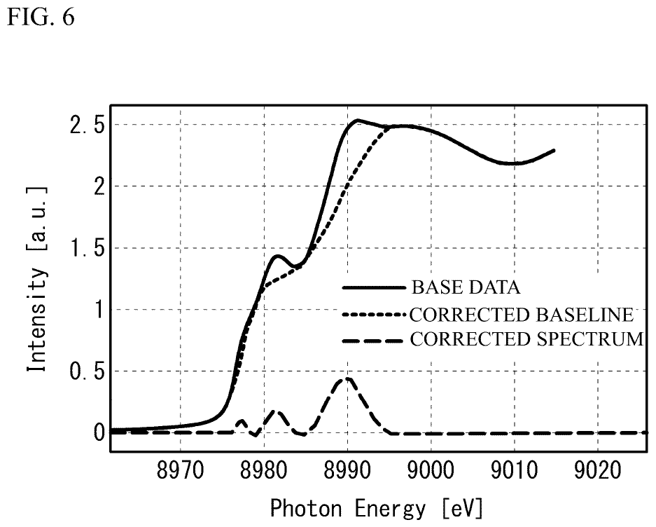

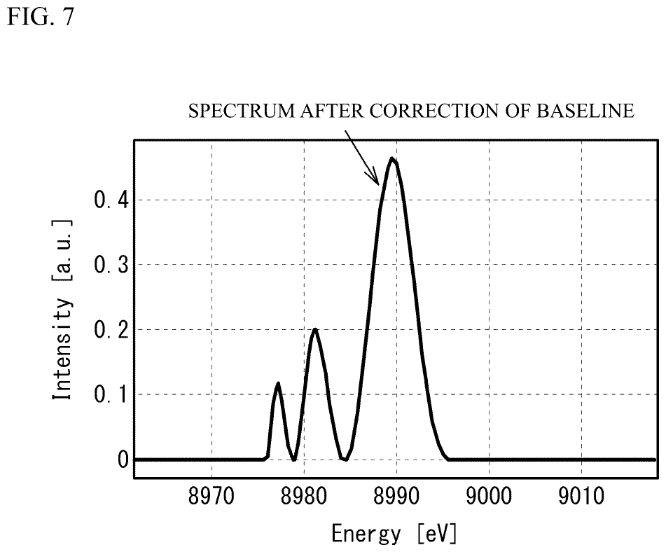

FIG. 5 is a measured spectrum obtained by X-ray absorption spectroscopy. FIG. 6 illustrates the result of estimating the baseline for the measured spectrum in FIG. 5 using the nonlinear least squares method. FIG. 7 illustrates only the corrected spectrum extracted from FIG. 6. FIG. 7 illustrates the correction result in which the peak shape of the measured spectrum is clearly maintained without losing the peaks.

However, in order to obtain the corrected spectrum illustrated in FIG. 7, it is necessary to appropriately select the parameters λ and ratio, and trial and error is unavoidable.

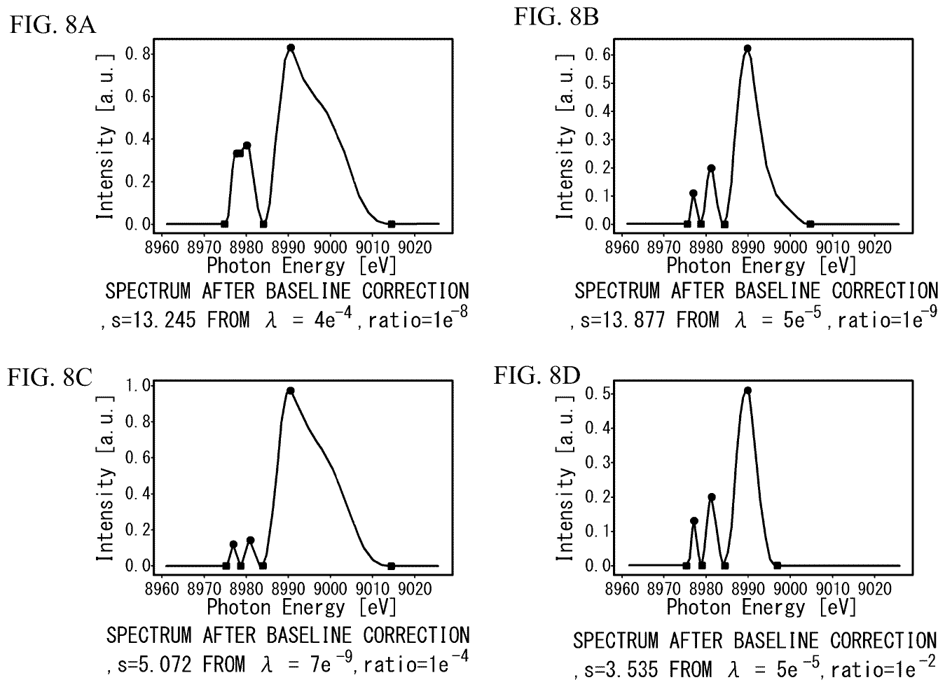

Therefore, according to this embodiment, the values of the parameter λ and the parameter ratio are respectively changed from, for example, 1×e⁻² to 1×e⁻¹⁰, and the baseline estimation is repeated. FIG. 8A to FIG. 8D illustrate the results when the values of the parameter λ and the parameter ratio are changed. In each case, the number of peaks is three (circled areas), and this is the largest in the correction spectrum obtained by changing the values of the parameter λ and the parameter ratio from 1×e⁻² to 1×e⁻¹⁰.

Among FIG. 8A to FIG. 8D, the spectrum with the smallest peak area s of the entire spectrum is FIG. 8D. Therefore, FIG. 8D is the optimal correction spectrum.

According to this embodiment, the optimal baseline correction is possible by selecting the correction spectrum with the largest number of peaks, and then selecting the correction spectrum with the smallest peak area s from the selected correction spectrum.

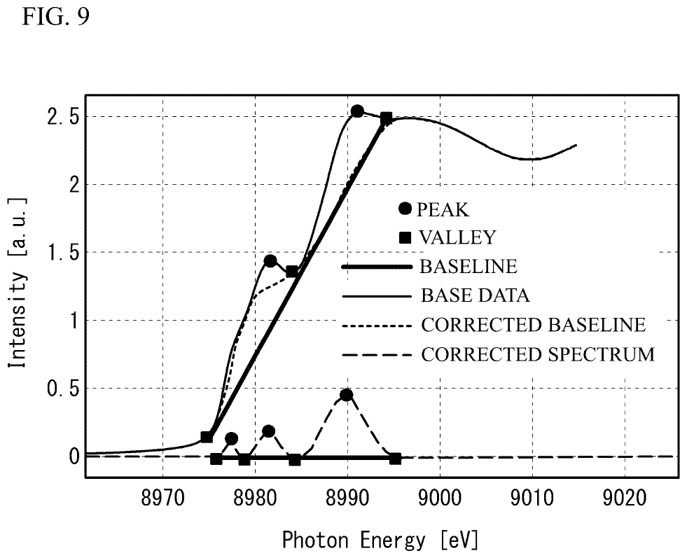

FIG. 9 is a diagram illustrating the base data, the corrected baseline, the corrected spectrum, and the baseline. The baseline is the baseline used when calculating the peak area. The peak area of the base data is the area of the region surrounded by the base data and the baseline. The peak area of the corrected spectrum is the area of the region surrounded by the corrected spectrum and the baseline.

The base data has two peaks, and the corrected spectrum has three peaks. In the corrected spectrum, there is a clear peak at 8975 eV to 8980 eV, whereas in the base data, there is only a slight bulge at that position and it is not recognized as a peak. In this way, the baseline processing according to this embodiment can bring out the buried peaks. On the other hand, there is a risk of crushing the peaks that existed before the baseline processing. Therefore, it is preferable that the number of peaks in this embodiment is limited to the number of peaks that existed before the baseline processing. Also, in consideration of bringing out the buried peaks, it is preferable that the peak area is limited to the area of the spectrum of the base data.

In the above example, when selecting a corrected spectrum, one or more corrected spectra with the maximum number of peaks are selected, and further, a corrected spectrum with the smallest peak area is selected, but this is not limited to this. For example, when selecting according to the number of peaks, a corrected spectrum with a number of peaks equal to or greater than a threshold may be selected. Also, when selecting a corrected spectrum according to the peak area, a corrected spectrum with a peak area equal to or less than a threshold may be selected. Also, in the above example, the parameters λ and ratio are optimized, but other parameters may be optimized.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention. For example, the above-described coolant may be cold water or an antifreeze solution.

What is claimed is:

1. A non-transitory computer-readable recording medium that stores a program causing a computer to execute a process, the process including:
an acquisition process of changing a parameter for identifying a baseline to multiple values to obtain multiple estimated baselines estimated for each of the multiple values, an identification process of identifying peaks in multiple graphs that represent differences between a base data of spectral data and each of the multiple estimated baselines, and a selection process of selecting a first graph from the multiple graphs according to a number of peaks and a peak area of each of the multiple graphs, when identifying the baseline using a nonlinear least squares method for the base data.

2. The medium as claimed in claim 1, wherein in the selection process, a graph is selected in which the number of peaks identified is equal to or greater than a threshold value.

3. The medium as claimed in claim 1, wherein in the selection process, a graph is selected in which the number of peaks identified is a maximum value.

4. The medium as claimed in claim 1, wherein in the selection process, among the graphs selected according to the number of peaks, a graph in which the peak area is equal to or smaller than a threshold is selected.

5. The medium as claimed in claim 1, wherein in the selection process, among the graphs selected according to the number of peaks, a graph in which the peak area is a minimum value.

6. The medium as claimed in claim 1, wherein the parameter includes a hyper parameter in the nonlinear least squares method.

7. The medium as claimed in claim 1, wherein the parameter is a parameter related to a rate of change of a weight when performing an iterative process while varying the weight in the nonlinear least squares method.

8. A calculation method comprising:
changing a parameter for identifying a baseline to multiple values to obtain multiple estimated baselines estimated for each of the multiple values, identifying peaks in multiple graphs that represent differences between a base data of spectral data and each of the multiple estimated baselines, and selecting a first graph from the multiple graphs according to a number of peaks and a peak area of each of the multiple graphs, when identifying the baseline using a nonlinear least squares method for the base data.

9. The method as claimed in claim 8, wherein in selecting, a graph is selected in which the number of peaks identified is equal to or greater than a threshold value.

10. The method as claimed in claim 8, wherein in the selecting, a graph is selected in which the number of peaks identified is a maximum value.

11. The method as claimed in claim 8, wherein in the selecting, among the graphs selected according to the number of peaks, a graph in which the peak area is equal to or smaller than a threshold is selected.

12. The method as claimed in claim 8, wherein in the selecting, among the graphs selected according to the number of peaks, a graph in which the peak area is a minimum value.

13. The method as claimed in claim 8, wherein the parameter includes a hyper parameter in the nonlinear least squares method.

14. The method as claimed in claim 8, wherein the parameter is a parameter related to a rate of change of a weight when performing an iterative process while varying the weight in the nonlinear least squares method.

15. An information processing device comprising:
a memory; and
a processor coupled to the memory and configured to:
acquire a base data of a spectral data; and
change a parameter for identifying a baseline to multiple values to obtain multiple estimated baselines estimated for each of the multiple values, identify peaks in multiple graphs that represent differences between the base data of spectral data and each of the multiple estimated baselines, and select a first graph from the multiple graphs according to a number of peaks and a peak area of each of the multiple graphs, when identifying the baseline using a nonlinear least squares method for the base data.

16. The information processing device as claimed in claim 15 wherein the processor is configured to select a graph in which the number of peaks identified is equal to or greater than a threshold value, when selecting the first graph.

17. The information processing device as claimed in claim 15 wherein the processor is configured to select a graph in which the number of peaks identified is a maximum value, when selecting the first graph.

18. The information processing device as claimed in claim 15 wherein the processor is configured to select a graph in which the peak area is equal to or smaller than a threshold, among the graphs selected according to the number of peaks.

19. The information processing device as claimed in claim 15 wherein the processor is configured to select a graph in which the peak area is a minimum value, among the graphs selected according to the number of peaks.

20. The information processing device as claimed in claim 15 wherein the parameter includes a hyper parameter in the nonlinear least squares method.
